(19) United States
(12) Patent Application Publication
(10) Pub. No.: US 2024/0260193 A1
(43) Pub. Date: Aug. 1, 2024

(54) DECOUPLING CAPACITOR BOOSTER MODULE

(71) Applicant: Intel Corporation, Santa Clara, CA (US)

(72) Inventors: Herh Nan Chen, Georgetown (MY); Kean Huat Leong, Georgetown (MY); Sze Lin Mak, Pulau Pinang (MY); Muhammad Danial Asyraf Abd Rahman, Kedah (MY)

(73) Assignee: Intel Corporation, Santa Clara, CA (US)

(21) Appl. No.: 18/102,394

(22) Filed: Jan. 27, 2023

(51) Int. Cl. H05K 1/18; H05K 1/11; H05K 1/14; H05K 3/34

(52) U.S. Cl. CPC H05K 1/181; H05K 1/115; H05K 1/144; H05K 1/145; H05K 3/3415; H05K 3/3431; H05K 2201/042; H05K 2201/096; H05K 2201/10015; H05K 2201/10545; H05K 2201/10636

(57) ABSTRACT

Microelectronic devices and systems include a decoupling capacitor module having any number of capacitors attached to a surface of a substrate such as a cored or coreless microelectronics board. The decoupling capacitor module is attached, by an opposing surface of the substrate, to a number of capacitors that are, in turn, mounted on a board such as a motherboard. Substrate mounted capacitors are vertically aligned with corresponding board mounted capacitors to provide vertically stacked capacitors.

### BACKGROUND

The electronics industry is continually striving to produce ever faster, smaller, and more efficient computing products, including, but not limited to, personal computers, servers, and portable products such as portable computers, laptops, tablets, and the like. A key contributor to central processor unit (CPU) compute performance is the load line (LL) number, which is representative of the constraint put on the voltage and current in the circuit. The LL is, in turn, dependent on the number of capacitors that are deployed on the motherboard (MB). To achieve improved LL, extra board area is needed for the increased number of capacitors. The increased number of capacitors achieve better LL for higher CPU performance. However, the downside is compromising on battery size and, in turn, battery life due to the area lost not being used for power supply. Furthermore, it may be advantageous in some contexts to have flexible MB compatibility and/or to have MBs be reused for future generations (i.e., by replacing the CPU and/or other components). However, such goals cannot be met when a current MB does not support the needed number of capacitors for the next generation components. Notably, future compatibility is broken when adding more capacitors is needed for performance improvements in the future generation products such as, for example, enabling enhanced voltage mode features.

It is with respect to these and other considerations that the present improvements have been needed. Such improvements may become critical as the desire to improve computing device performance becomes even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A illustrates a cross-sectional side view of a microelectronic device including a capacitor module mounted to underlying board mounted capacitors;

FIG. 1B illustrates an expanded cross-sectional side view of the capacitor module of the microelectronic device of FIG. 1A;

FIG. 2 illustrates a capacitor to microelectronics board coupling taken at a view of a cross-sectional plane of the microelectronic device of FIG. 1A;

FIG. 3 illustrates a capacitor to substrate coupling taken at a view of a cross-sectional plane of the microelectronic device of FIG. 1A;

FIG. 4 illustrates a cross-sectional side view of the microelectronic device of FIG. 1A overlayed with an extended microelectronics board having additional microelectronics board mounted capacitors;

FIG. 5A illustrates an expanded cross-sectional side view of a capacitor module with lateral misalignment of capacitors;

FIG. 5B illustrates an overlay of a capacitor to microelectronics board coupling and a capacitor to substrate coupling taken at cross-sectional planes of the capacitor module of FIG. 5A;

FIG. 6A illustrates an expanded cross-sectional side view of a capacitor module with different sized capacitors;

FIG. 6B illustrates an overlay of a capacitor to microelectronics board coupling and a capacitor to substrate coupling taken at cross-sectional planes of the capacitor module of FIG. 6A;

FIG. 7 is a flow diagram illustrating an example process for forming a microelectronic device including a capacitor module mounted to underlying board mounted capacitors;

FIGS. 8A, 8B, 8C, 8D, 8E, 8F, 8G, and 8H illustrate cross-sectional side views of device structures as the operations of the process of FIG. 7 are performed;

FIG. 9 illustrates an example capacitor layout of a capacitor module taken at a view of cross-section in FIG. 8H;

FIG. 10 illustrates an example microelectronic device assembly including a capacitor module such as a decoupling capacitor boost module;

FIG. 11 illustrates exemplary systems employing a capacitor module such as a decoupling capacitor boost module; and

FIG. 12 is a functional block diagram of an electronic computing device, all in accordance with some embodiments.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure.

As used herein, the terms “monolithic”, “monolithically integrated”, and similar terms indicate the components of the monolithic overall structure form an indivisible whole not reasonably capable of being separated. The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials. Here, the term “coreless” generally refers to a substrate of an integrated circuit package having no core. The lack of a core allows for higher-density package architectures. as the through-vias have relatively large dimensions and pitch compared to high-density interconnects.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate. Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric. Here, the term “bond pad” generally refers to metallization structures that terminate integrated traces and vias in integrated circuit packages and dies. The term “solder pad” may be occasionally substituted for “bond pad” and carries the same meaning. Here, the term “solder bump” generally refers to a solder layer formed on a bond pad. The solder layer typically has a round shape, hence the term “solder bump”. Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

As discussed, increasing the number of capacitors such as decoupling capacitors in an electronic system may provide for support higher performance including higher CPU performance. However, increasing the number of capacitors takes up space on the motherboard, which can lead to downsides such as reduced battery size, increased device form factor, and others. In some embodiments, a decoupling capacitor booster module (DCBM) is disclosed. The capacitor module includes a number of capacitors mounted on a substrate such that the substrate includes metallization routing coupled to the capacitors. The capacitor module is then mounted onto corresponding capacitors that are, in turn, mounted on a microelectronics board such as a motherboard. For example, the capacitor module may be an add-in card populated with capacitors. The capacitors of the capacitor module are vertically aligned with the capacitors mounted on the microelectronics board. As used herein, the term vertically aligned indicates at least portions of the footprints of the capacitors overlap vertically. For example, perimeters of the capacitors (i.e., with perimeter being defined as a path that outlines the capacitor) may be defined such that the perimeters at least partially overlap vertically. In some embodiments, the capacitors are vertically aligned such that the centerlines of the capacitors are substantially aligned. The term centerline indicates a line extending vertically through an axis of symmetry of the object. The term vertical is used to indicate orthogonal to the plane of the device or system as established by a plane of the microelectronics board.

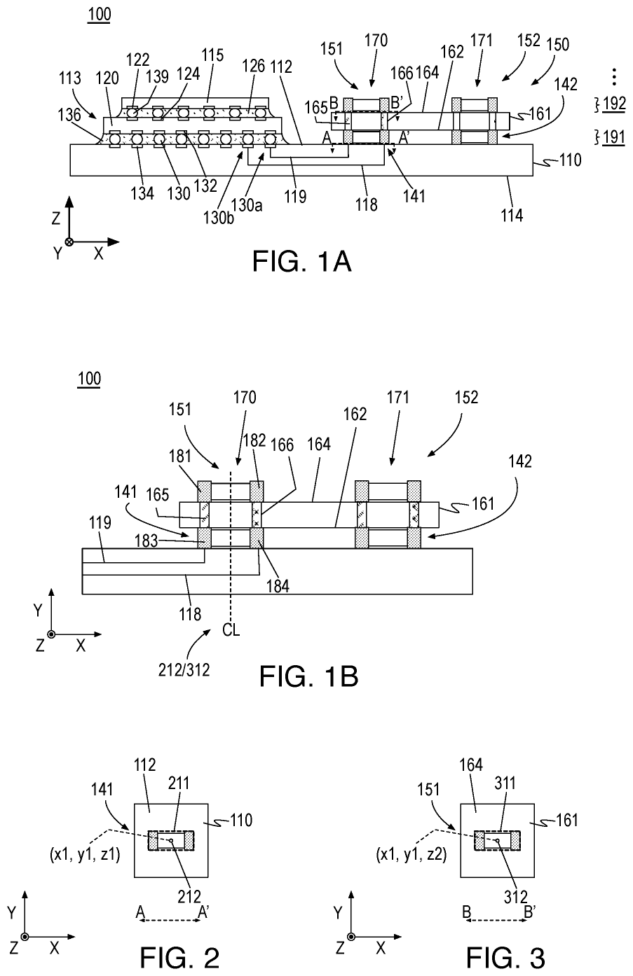

FIG. 1A illustrates a cross-sectional side view of a microelectronic device 100 including a capacitor module 150 mounted to underlying board mounted capacitors 141, 142, arranged in accordance with some embodiments. FIG. 1B illustrates an expanded cross-sectional side view of capacitor module 150 of microelectronic device 100. As shown in FIG. 1A, microelectronic device 100 includes a microelectronics board 110 (or substrate). At least one integrated circuit device 120 is attached to a first surface 112 of microelectronics board 110 by a number of device interconnects 130. Device interconnects 130 may extend between bond pads 132 formed in or on an active surface of integrated circuit device 120 and substantially mirror-image bond pads 134 formed in or on first surface 112 of microelectronics board 110. Integrated circuit device 120 may further include a back surface opposite the active surface thereof. Similarly, an integrated circuit device 115 may be attached to the back surface of integrated circuit device 120 by a number of device interconnects 139 that extend between bond pads 122 formed in or on an active surface of integrated circuit device 115 and bond pads 124 formed in or the back surface of integrated circuit device 120. Integrated circuit device 115 may further include a back surface opposite the active surface thereof.

Integrated circuit devices 120, 115 may be any appropriate electronic devices, including, but not limited to, a microprocessor, a chipset, a graphics device, a wireless device, a memory device, an application specific integrated circuit device, combinations thereof, stacks thereof, or the like. Although illustrated with a multi-device stack including an integrated circuit package 113 and a backside mounted integrated circuit device 115, other integrated circuit device structures may be used such as single integrated circuit packages or the like. Device interconnects 130, 139 may be any appropriate electrically conductive material or structure, including but not limited to, solder balls, metal bumps or pillars, or metal filled epoxies. For example device interconnects 130, 139 may be solder balls formed from tin, lead/tin alloys, tin alloys (e.g., tin/bismuth, tin/silver, tin/silver/copper, or tin/copper), copper bumps or pillars, or metal bumps or pillars coated with a solder material. In some embodiments, interconnects 130 are a ball grid array. In some embodiments, interconnects 139 are solder bumps. Underfill material 136, 126 such as an epoxy material, may be disposed between surfaces of integrated circuit device 120 and microelectronics board 110 and between surfaces of integrated circuit device 120, 115.

Microelectronics board 110 may include dielectric material layers, which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, as well as laminates or multiple layers thereof, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like. For example, microelectronics board 110 may be a motherboard.

Also as shown in FIG. 1A, microelectronic device 100 includes a number of capacitors 141, 142 attached to microelectronics board 110. Capacitors 141, 142 may be any suitable capacitors of any rating pertinent to deployment in microelectronic device 100, and any number of capacitors may be deployed. Capacitors 141, 142 may be attached to microelectronics board 110 using any suitable technique or techniques such as surface mount techniques. In some embodiments, capacitors 141, 142 are attached to microelectronics board 110 using a solder joint, as illustrated further herein below. With reference to FIG. 1B, a first electrode 183 of capacitor 141 may be coupled by a conductive route 119 to an interconnect 130a to integrated circuit device 120 and a second electrode 184 of capacitor 141 may be coupled by a conductive route 118 to an interconnect 130b to integrated circuit device 120. Similar connections may be made to electrodes of capacitor 142 (not shown).

Conductive routes 118, 119 may be a combination of conductive traces and conductive vias that extend through dielectric material layers of microelectronics board 110. Such conductive traces and conductive vias, and processes of forming them, are known in the art and are not shown for clarity of presentation. The conductive traces and the conductive vias may be made of any appropriate conductive material, including, but not limited to, metals, such as copper, silver, nickel, gold, and aluminum. As will be understood by those skilled in the art, the electronic substrate 110 may be a cored substrate or a coreless substrate.

With reference to FIG. 1A, capacitors 141, 142 may be characterized as first level capacitors 191 (or L1 capacitors) as they are directly mounted to microelectronics board 110. Capacitor module 150 includes a substrate 161 having a first surface 162 and an opposing second surface 164. Capacitors 151, 152 are mounted to second surface 164 using any suitable technique or techniques such as surface mount techniques. Capacitors 151, 152 may be characterized as second level capacitors 192 (or L2 capacitors) as they are stacked over first level capacitors 191. As shown, capacitor 151 and capacitor 141 are vertically aligned to form a capacitor stack 170. Capacitor stack 170 includes capacitor 141, a portion of substrate 161, and capacitor 151. Similarly, capacitor 152 and capacitor 142 are vertically aligned to form a capacitor stack 171 such that capacitor stack 171 includes capacitor 142, a portion of substrate 161, and capacitor 152. Capacitor module 150 may have any lateral dimensions (e.g., in the x-y plane). In some embodiments, capacitor module 150 is about 1 to 2 cm². Furthermore, capacitor module 150 may include any number of capacitors such as 10 to 20 capacitors. In some embodiments, capacitor module 150 has the same number of capacitors as attached to microelectronics board 110. For example, the maximum quantity of capacitors of capacitor module 150 may be dependent on the array capacitor count available on microelectronics board 110.

With reference to FIG. 1B, capacitor stack 170 may also include vias 165, 166. Via 165 directly couples electrode 181 of capacitor 151 to electrode 183 of capacitor 141 and via 166 directly couples electrode 182 of capacitor 151 to electrode 184 of capacitor 141. In some embodiments, via 165 is a power via and via 166 is a ground via. As used herein, the term via indicates a conductive material that is aligned vertically (e.g., extends lengthwise orthogonal to a plane of substrate 161). For example, vias 165, 166 may be conductive vias made of any appropriate conductive material, including, but not limited to, metals, such as copper, silver, nickel, gold, and aluminum.

Furthermore, electrode 181 of capacitor 151 is directly routed or connected to interconnect 130a to integrated circuit device 120 and electrode 183 of capacitor 141 is directly routed or connected to interconnect 130a to integrated circuit device 120 by shared conductive route 119. For example, electrode 181 is directly coupled to via 165, which is directly coupled to electrode 183, which is directly coupled to conductive route 119 to interconnect 130a. For example, the electrode 181, via 165, electrode 183, conductive route 119, and interconnect 130a direct routing may be a direct power routing for integrated circuit device 120. Similarly, electrode 182 of capacitor 151 is directly routed or connected to interconnect 130b to integrated circuit device 120 and electrode 184 of capacitor 141 is directly routed or connected to interconnect 130b to integrated circuit device 120 by shared conductive route 118. For example, the electrode 182, via 166, electrode 184, conductive route 118, and interconnect 130b direct routing may be a direct ground routing for integrated circuit device 120.

As shown, microelectronic device 100 includes any number of capacitor stacks 170, 171 such that each capacitor stack 170, 171 includes a first level capacitor 191 attached to surface 112 of microelectronics board 110 and a second level capacitor 192 over the first level capacitor 191 with substrate 161 therebetween. In some embodiments, each capacitor stack 170, 171 includes a vertically aligned power via (i.e., via 165) and a vertically aligned ground via (i.e., via 166) directly connecting corresponding electrodes (i.e., electrodes 181, 183 and electrodes 182, 184, respectively) of the first and second level capacitors 191, 192. Although illustrated with respect to two capacitor levels, any number may be deployed. For example, a second capacitor module similar to capacitor module 150 may be mounted to capacitor module 150, a third capacitor module may be mounted to the second capacitor module, and so on.

Substrate 110 may include the same or similar materials microelectronic device 100. For example, substrate may include dielectric material layers such as build-up films and/or solder resist layers. In some embodiments, substrate 110 is a cored substrate. In some embodiments, substrate 110 is a coreless substrate. In some embodiments, substrate 110 is a printed circuit board. In some embodiments, substrate 110 is an electronics card.

As discussed, capacitor stack 170 includes a stack of vertically aligned capacitors 141, 151 with substrate 161 therebetween and capacitor stack 171 includes a stack of vertically aligned capacitors 142, 152 with substrate 161 therebetween. Such vertical alignment may include selecting capacitors that are the same form factor (i.e., same dimensions in the x-y plane) and fully aligning them such that capacitors 141, 151 are within the shadows or perimeters of capacitors 142, 152. In some embodiments, capacitors 151, 152 on substrate 161 of capacitor module 150 are placed such that capacitors 151, 152 are directly aligned vertically with corresponding capacitors 141, 142 on microelectronics board 110. Such alignment may advantageously provide the shortest loop inductance path to interconnects 130 (e.g., ball grid array) of integrated circuit package 113.

FIG. 2 illustrates a capacitor to microelectronics board coupling taken at a view of the cross-section at plane A-A′ in FIG. 1A, arranged in accordance with some embodiments. FIG. 3 illustrates a capacitor to substrate coupling taken at a view of the cross-section at plane B-B′ in FIG. 1A, arranged in accordance with some embodiments. As shown in FIG. 2, capacitor 141 may have a perimeter 211 that surrounds and outlines capacitor 141. Perimeter 211 may outline capacitor 141 in detail or perimeter 211 may be a rectangle or rectilinear shape that has vertices at defined corners of capacitor 141. With reference to FIG. 1B, a centerline 212 of capacitor 141 may also be defined such that centerline 212 extends vertically (e.g., in the z-dimension) orthogonal to microelectronics board 110 (e.g., the x-y plane) and such that centerline 212 is at a center of the object such as an axis of symmetry of the shape of capacitor 141 in the x-y plane. In examples where capacitor 141 is not symmetrical, centerline 212 may be at a center of mass of capacitor 141. In the illustrated example, centerline 212 is at a position of (x1, y1) in the x-y plane and a vertical center of capacitor 141 is positioned at z1 in the z-dimension, giving capacitor 141 a position of (x1, y1, z1).

Similarly, capacitor 151 has a perimeter 311 that surrounds and outlines capacitor 151. Referring now to FIGS. 3 and 1B, a centerline 312 of capacitor 151 extends vertically (e.g., in the z-dimension) orthogonal to microelectronics board 110 (e.g., the x-y plane) such that centerline 312 is at a lateral center of capacitor 151 such as an axis of symmetry of the shape of capacitor 151 in the x-y plane. As shown, centerline 312 is also at a position of (x1, y1) in the x-y plane. But, a vertical center of capacitor 151 is positioned at z2 in the z-dimension, giving capacitor 151 a position of (x1, y1, z2). In this example, the lateral form factors of capacitors 141, 151 are the same. As used herein the term lateral form factor indicates the size and shape of an object such as capacitors 141, 151 in the x-y plane. For example, at a mounting surface or vertical center thereof, capacitors 141, 151 may have the same size and shape at a cross-section taken in the x-y plane. In some embodiments, capacitors 141, 151 have shared lateral form factor and capacitors 141, 151 are directly vertically aligned such that centerline 212 of capacitor 141 and centerline 312 of capacitor 151 are aligned.

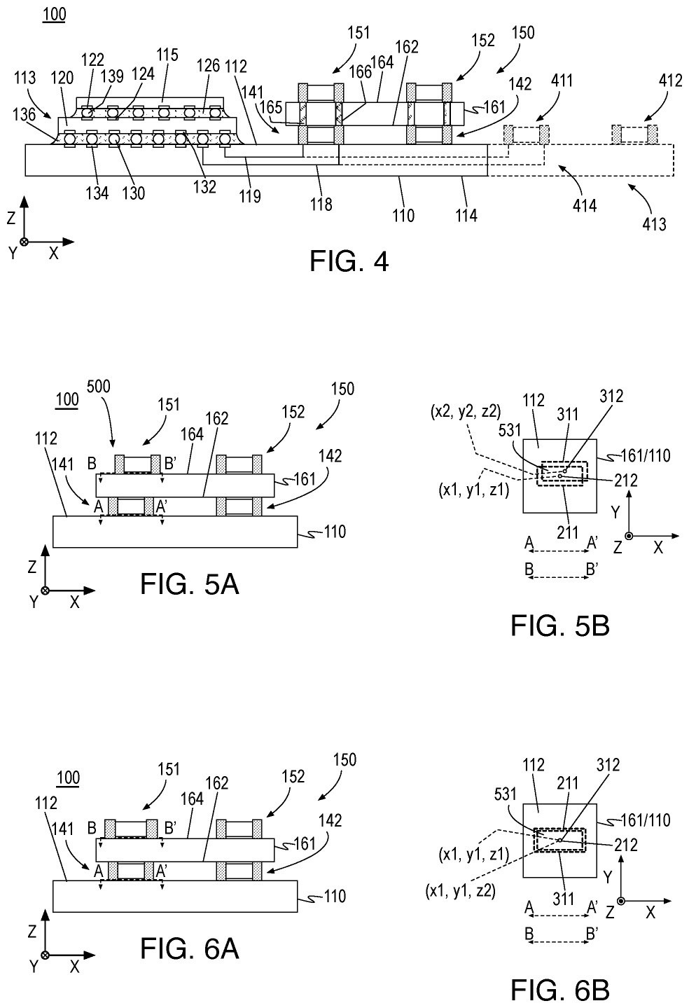

FIG. 4 illustrates a cross-sectional side view of microelectronic device 100 overlayed with an extended microelectronics board having additional microelectronics board mounted capacitors, arranged in accordance with some embodiments. As shown in FIG. 4, if capacitor module 150 were removed, to provide the same capacitor support, microelectronics board 110 would need extension portion 413, additional capacitors 411, 412 would be attached to extension portion 413 of microelectronics board 110, and longer conduction routes 414 would be necessitated.

In contrast, deployment of capacitor module 150 in microelectronic device 100, offers the advantages of increased performance (e.g., a greater number of capacitors) at the size of microelectronics board 110, reduced loop inductance (e.g., as otherwise induced by longer conduction routes 414), and others. In some embodiments, deployment of capacitor module 150 provides microelectronics board 110 area savings for the same quantity of capacitors. In some embodiments, capacitor module 150 allows scalability such that microelectronics board 110 may be designed in a standard power delivery performance configuration (e.g., absent capacitor module 150) and a premium power delivery performance configuration (e.g., for higher CPU core frequency) when capacitor module 150 is inserted. Such techniques provide design and fabrication efficiencies. In some embodiments, capacitor module 150 provides flexibility through the ability to attach different value of capacitors on capacitor module 150 for different performance target(s) without changing the capacitors deployed on microelectronics board 110. Other advantages will be evident based on the present disclosure.

FIG. 5A illustrates an expanded cross-sectional side view of capacitor module 150 of microelectronic device 100 with lateral misalignment 500 of capacitors 141, 151, arranged in accordance with some embodiments. FIG. 5B illustrates an overlay of the capacitor to microelectronics board coupling taken at a view of the cross-section at plane A-A′ in FIG. 5A with the capacitor to substrate coupling taken at a view of the cross-section at plane B-B′ in FIG. 5A. Notably, the overlay illustrates a lateral offset of capacitors 141, 151.

As shown in FIG. 5B, capacitor 141, as illustrated with respect to perimeter 211, has a centerline 212, as discussed above. Similarly, capacitor 151, as illustrated with respect to perimeter 311, has a centerline 312. In the illustrated example, centerline 212 extends vertically orthogonal to microelectronics board 110 such that centerline 212 is at a position of (x1, y1) in the x-y plane and a vertical center of capacitor 141 is positioned at z1 in the z-dimension, giving capacitor 141 a position of (x1, y1, z1). In a similar manner, centerline 312 of capacitor 151 extends vertically orthogonal to microelectronics board 110 such that centerline 312 is at a position of (x2, y2) in the x-y plane and a vertical center of capacitor 151 is positioned at z2 in the z-dimension, giving capacitor 151 a position of (x2, y2, z2).

In the example of FIGS. 5A and 5B, centerlines 212, 312 are offset with respect to one another by (x1-x2, y1-y2). However, capacitor 141 and capacitor 151 are vertically aligned such that at least a portion 531 of perimeters 211, 311 are overlapping when projected onto the same x-y plane. Such misalignment may be allowable (particularly in the y-dimension) while providing the discussed direct and vertically aligned power and ground vias (i.e., vias 165, 166). In some embodiments, capacitor 141 has perimeter 211 and at least a portion 531 of capacitor 151 is vertically aligned within perimeter 211 of capacitor 141. In some embodiments, capacitor 151 has perimeter 311 and at least a portion 531 of capacitor 141 is vertically aligned within perimeter 311 of capacitor 151.

FIG. 6A illustrates an expanded cross-sectional side view of capacitor module 150 of microelectronic device 100 with different sized capacitors 141, 151, arranged in accordance with some embodiments. FIG. 6B illustrates an overlay of the capacitor to microelectronics board coupling taken at a view of the cross-section at plane A-A′ in FIG. 6A with the capacitor to substrate coupling taken at a view of the cross-section at plane B-B′ in FIG. 6A. Notably, the overlay illustrates a size difference of capacitors 141, 151. In some embodiments, both the lateral offset between capacitors 141, 151 illustrated in FIGS. 5A and 5B and the size difference of capacitors 141, 151 illustrated in FIGS. 6A and 6B is present.

As shown in FIG. 6B, capacitor 141, as illustrated with respect to perimeter 211, has a centerline 212. Similarly, capacitor 151, as illustrated with respect to perimeter 311, has a centerline 312, which in the example of FIGS. 6A and 6B, is aligned with centerline 212. Notably, centerline 212 extends vertically orthogonal to microelectronics board 110 such that centerline 212 is at a position of (x1, y1) in the x-y plane and a vertical center of capacitor 141 is positioned at z1 in the z-dimension, giving capacitor 141 a position of (x1, y1, z1). Similarly, centerline 312 of capacitor 151 extends vertically orthogonal to microelectronics board 110 such that centerline 312 is at a position of (x1, y1) in the x-y plane and a vertical center of capacitor 151 is positioned at z2 in the z-dimension, giving capacitor 151 a position of (x1, y1, z2).

In the example of FIGS. 6A and 6B, centerlines 212, 312 are aligned with one another but the lateral form factors of capacitors 141, 151 differ such that capacitor 151 is larger in both the x- and y-dimensions than capacitor 141. Although illustrated with capacitor 151 being larger in both the x- and y-dimensions, capacitor 151 may be larger in the x- or y-dimensions only. Alternatively, capacitor 141 may be larger than capacitor 151 in the x-dimension, the y-dimension, or both. In any event, capacitor 141 and capacitor 151 are vertically aligned such that at least a portion 531 of perimeters 211, 311 are overlapping when projected onto the same x-y plane. Such size difference and/or misalignment may be allowable while the discussed direct and vertically aligned power and ground vias (i.e., vias 165, 166) are maintained.

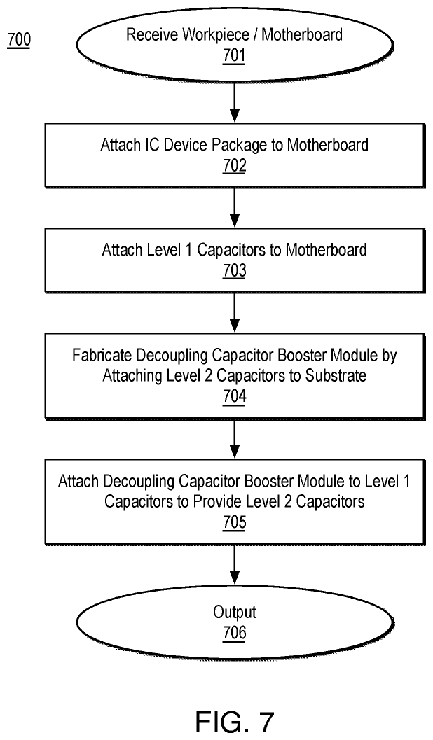

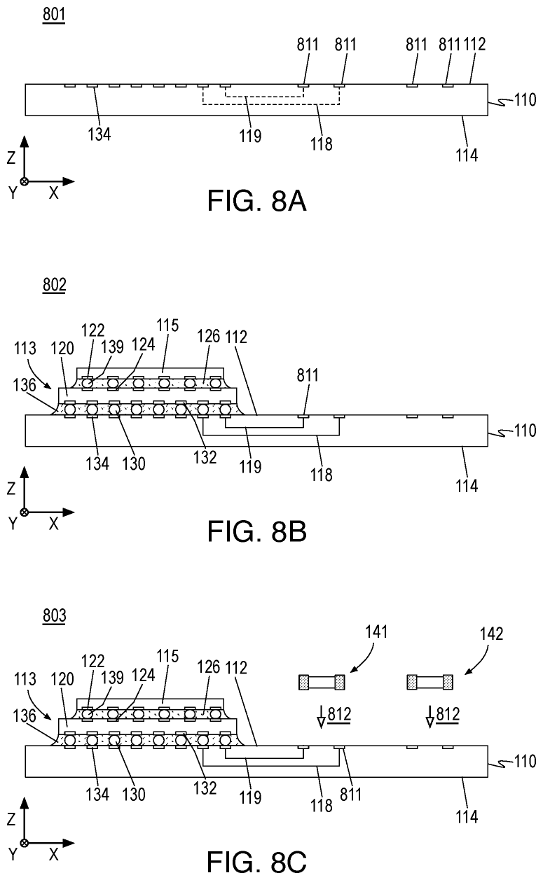

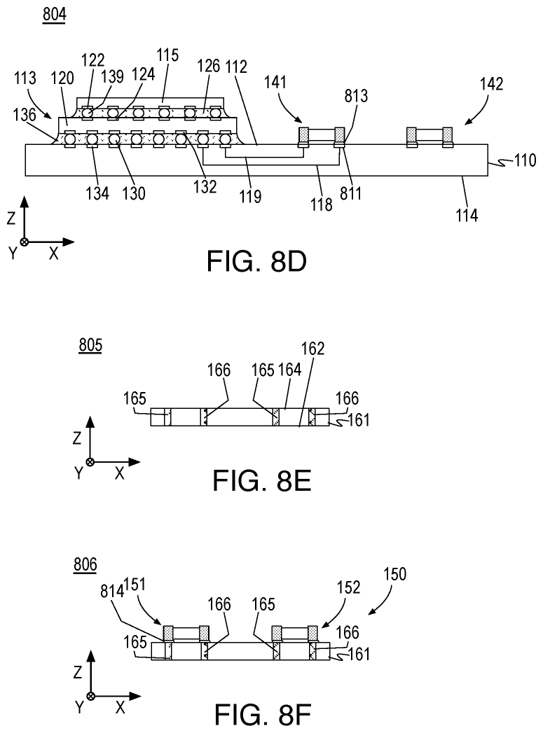

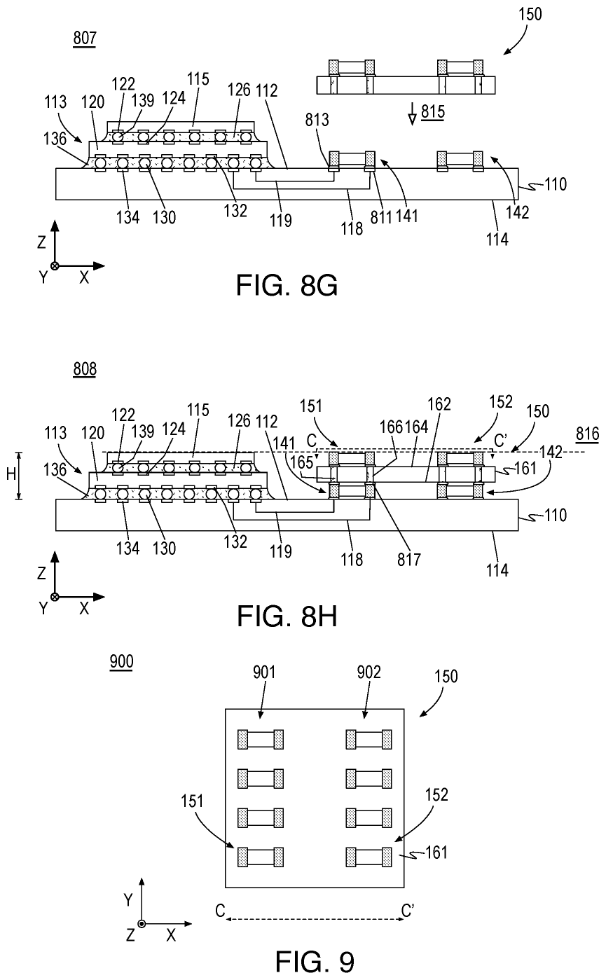

FIG. 7 is a flow diagram illustrating an example process 700 for forming a microelectronic device including a capacitor module mounted to underlying board mounted capacitors, arranged in accordance with some embodiments. FIGS. 8A, 8B, 8C, 8D, 8E, 8F, 8G, and 8H illustrate cross-sectional side views of device structures as the operations of process 700 are performed, arranged in accordance with some embodiments. As shown, process 700 begins at operation 701, where a workpiece such as a microelectronics board is received for processing. The microelectronics board may be any suitable microelectronics board, substrate, motherboard, or the like. The microelectronics board may be preprocessed to form exposed metal bond pads embedded in a dielectric layer for subsequent bonding.

FIG. 8A illustrates an example device structure 801. As shown, device structure 801 includes microelectronics board 110 having first surface 112 and an opposing second surface 114. Microelectronics board 110 includes exposed bond pads 134. In the example of FIG. 8A, microelectronics board 110 also includes exposed bond pads 811 for attachment of capacitors. Although illustrated with respect to bond pads 811, any suitable conductive features may be exposed for subsequent capacitor bonding. As shown, microelectronics board 110 further includes pre-fabricated conductive routes 118, 119.

Returning to FIG. 7, processing continues at operation 702, where an integrated circuit device such as an integrated circuit device package is attached to the microelectronics board or motherboard. The integrated circuit device may be attached using any suitable technique or techniques. In some embodiments, the integrated circuit device is attached using a ball grid array surface mount techniques. However, the integrated circuit device may be attached using hybrid bonding, or other techniques.

FIG. 8B illustrates an example device structure 802 similar to device structure 801 after the attachment of integrated circuit device 120 to microelectronics board 110 and the attachment of integrated circuit device 115 to integrated circuit device 120. In some embodiments, integrated circuit device 120 is first attached using ball grid array surface mount techniques and integrated circuit device 115 is then attached using bump attachment techniques. Underfill materials 136, 126 may then be formed. Alternatively, integrated circuit device 115 may first be attached to integrated circuit device 120, and the assembly may then be attached to microelectronics board 110.

Returning to FIG. 7, processing continues at operation 703, where level 1 capacitors are attached to the microelectronics board. The level 1 capacitors may be attached to the microelectronics board using any suitable technique or techniques such as surface mount techniques, solder techniques, or the like. Notably, operations 702, 703 may be performed in any order.

FIG. 8C illustrates an example device structure 803 similar to device structure 802 as capacitors 141, 142 (e.g., first level capacitors) are directly coupled to microelectronics board 110 by attachment operations 812. For example, attachment operations 812 may include pick and place operations. FIG. 8D illustrates an example device structure 804 similar to device structure 803 after the attachment of capacitors 141, 142 to microelectronics board 110. In the example of FIG. 8D, capacitors 141, 142 are attached to microelectronics board 110 using solder joints 813. However, any suitable conductive joints may be used.

Returning to FIG. 7, processing continues at operation 704, where a capacitor module (decoupling capacitor boost module) is fabricated by attaching level 2 capacitors to a substrate. In some embodiments, the substrate is pre-fabricated to include the power and ground vias discussed herein. The level 2 capacitors may be attached to the substrate using any suitable technique or techniques such as surface mount techniques, solder techniques, or the like.

FIG. 8E illustrates an example device structure 805. As shown, device structure 805 includes substrate 161 having first surface 162 and opposing second surface 164. Substrate 161 includes vias 165, 166. In some embodiments, substrate 161 includes exposed bond pads (not shown); however, any suitable conductive features may be exposed for subsequent capacitor bonding. For example, pads or top surfaces of vias 165, 166 may be exposed for coupling to level 1 and level 2 capacitors.

FIG. 8F illustrates an example device structure 806 similar to device structure 805 after the attachment of capacitors 151, 152 to substrate 161. In the example of FIG. 8F, capacitors 151, 152 are attached to substrate 161 using solder joints 814. However, any suitable conductive joints may be used. As shown the electrodes of capacitors 151, 152 are aligned to and contacted with vias 165, 166. For example, device structure 806 is a capacitor module that may be flexibly applied to any microelectronics board having level 1 capacitors.

Returning to FIG. 7, processing continues at operation 705, where the capacitor module (decoupling capacitor boost module) fabricated at operation 704 is attached to the level 1 capacitors that were previously attached to the microelectronics board at operation 703. The capacitor module may be attached to the level 1 capacitors using any suitable technique or techniques such as surface mount techniques, solder techniques, or the like. Notably, one or both of operations 703, 705 may be performed prior to operation 702.

FIG. 8G illustrates an example device structure 807 similar to device structure 804 (refer to FIG. 8D) as capacitor module 150 (including second level capacitors 151, 152) is directly coupled to capacitors 141, 142 by attachment operation 815. For example, attachment operation 815 may include a pick and place operation followed by a solder operation. FIG. 8H illustrates an example device structure 808 similar to device structure 807 after the attachment of module 150 (including second level capacitors 151, 152) to capacitors 141, 142. In the example of FIG. 8H, module 150 is attached to capacitors 141, 142 using solder joints 817. In some embodiments, capacitor module 150 is advantageously directly attached on top of capacitors 141, 142, which were previously attached to microelectronics board 110, by soldering on the terminals of capacitors 141, 142.

As shown with respect to device structure 808, in some embodiments, a vertical offset or height, H, is provided by the assembly including integrated circuit devices 120, 115. In some embodiments, a combined height of capacitor module 150 and capacitors 141, 142 is less than or equal to the vertical offset or height, H. In some embodiments, substantially coplanar surfaces 816 are provided by the top surface of the assembly including integrated circuit devices 120, 115 and the top surface of capacitor module 150. For example, the substantially coplanar surfaces may be at vertical offset or height, H, above top surface 112 of microelectronics board 110. Capacitors 141, 142 and capacitors 151, 152 may be arrayed over microelectronics board 110 in any suitable pattern. For example, capacitor module 150 may take advantage of any z-height available. Although illustrated herein with respect to capacitor module 150 and capacitors 141, 142 being placed on top surface 112, capacitor module 150 and capacitors 141, 142 may be placed on top surface 112, bottom surface 114, or both.

Returning to FIG. 7, processing continues at operation 706, where the microelectronics board, integrated circuit device(s), and capacitor stack assembly is output for continued assembly and incorporation into an electronic device.

FIG. 9 illustrates an example capacitor layout 900 of capacitor module 150 taken at a view of the cross-section at plane C-C′ in FIG. 8H, arranged in accordance with some embodiments. As shown, in some embodiments, columns 901, 902 of capacitors including capacitors 151, 152 are arrayed over substrate 161. It is noted, the same or similar columns of underlying capacitors are provided on microelectronics board 110. Although illustrated with respect to columns 901, 902 of capacitors, the capacitors on substrate 161 (and the corresponding underlying capacitors) may be arranged in any suitable pattern.

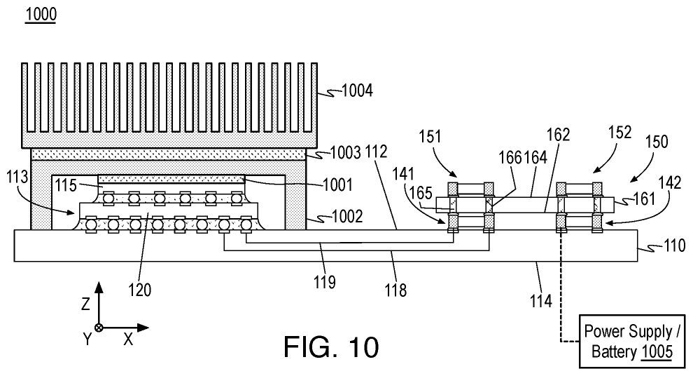

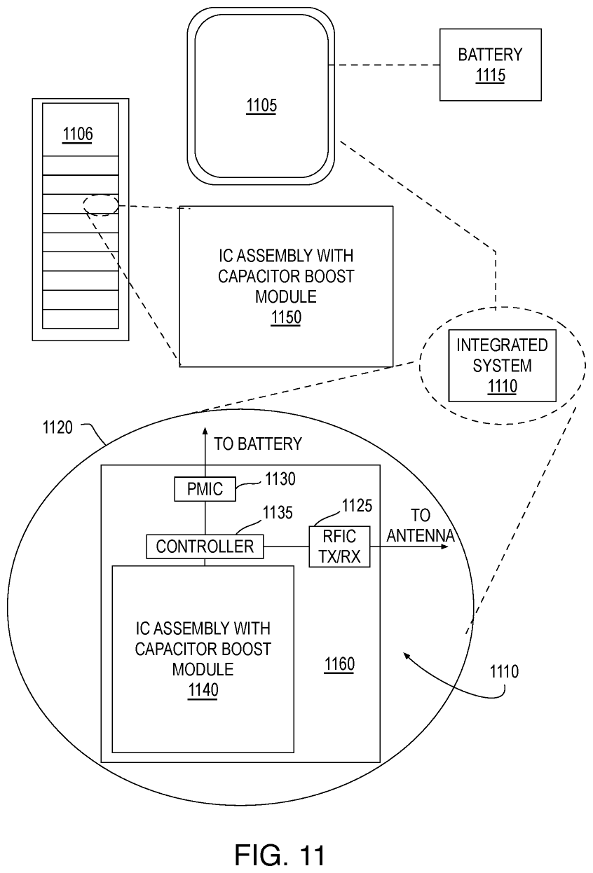

FIG. 10 illustrates an example microelectronic device assembly 1000 including a capacitor module such as a decoupling capacitor boost module, in accordance with some embodiments. As shown, microelectronic device assembly 1000 includes integrated circuit devices 120, 115 attached to microelectronics board 110. In the context of FIG. 10, microelectronic device assembly 1000 also includes capacitor module 150, as discussed herein. Microelectronic device assembly 1000 may include a power supply and/or battery 1005 coupled to one or more of capacitors 141, 142, 151, 152 or other components of microelectronic device assembly 1000. The power supply may include a battery, voltage converter, power supply circuitry, or the like.

Microelectronic device assembly 1000 further includes a thermal interface material (TIM) 1001 disposed on a top surface of integrated circuit device 115. TIM 1001 may include any suitable thermal interface material and may be characterized as TIM 1. Integrated heat spreader 1002 having a surface on TIM 1001 extends over integrated circuit devices 120, 115, and is mounted to microelectronics board 110. Microelectronics board 110 may include any suitable substrate such as a motherboard, interposer, or the like. Microelectronic device assembly 1000 further includes TIM 1003 disposed on a top surface of integrated heat spreader 1002. TIM 1003 may include any suitable thermal interface material and may be characterized as TIM 2. TIM 1001 and TIM 1003 may be the same materials or they may be different. Heat sink 1004 (e.g., an exemplary heat dissipation device or thermal solution) is on TIM 1003 and dissipates heat generated by integrated circuit devices 120, 115. Although illustrated with respect to microelectronic device assembly 1000, the various capacitor modules discussed herein may be deployed in any suitable architecture and form factor. For example, microelectronic device assembly 1000 may be used in desktop and server form factors. In other contexts, a heat solution such as a heat pipe or heat spreader may be mounted directly on TIM 1001. Such assemblies may be used in smaller form factor devices. Other heat dissipation devices may be used in concert with the heat removal enhancement structures discussed herein. As used herein, the term heat exchanger indicates a structure or device inclusive of any such heat removal solutions inclusive of integrated heat spreaders, heat sinks, heat pipes, and so on.

FIG. 11 illustrates exemplary systems employing a capacitor module such as a decoupling capacitor boost module, in accordance with some embodiments. The system may be a mobile computing platform 1105 and/or a data server machine 1106, for example. Either may employ a capacitor module (decoupling capacitor boost module) as described elsewhere herein. Server machine 1106 may be any commercial server, for example including any number of high-performance computing platforms disposed within a rack and networked together for electronic data processing, which in the exemplary embodiment includes an IC die assembly 1150 with a capacitor module (decoupling capacitor boost module) as described elsewhere herein. Mobile computing platform 1105 may be any portable device configured for each of electronic data display, electronic data processing, wireless electronic data transmission, or the like. For example, mobile computing platform 1105 may be any of a tablet, a laptop computer, etc., and may include a display screen (e.g., a capacitive, inductive, resistive, or optical touchscreen), a chip-level or package-level integrated system 1110, and a battery 1115. Although illustrated with respect to mobile computing platform 1105, in other examples, chip-level or package-level integrated system 1110 and a battery 1115 may be implemented in a desktop computing platform, an automotive computing platform, an internet of things platform, or the like. As discussed below, in some examples, the disclosed systems may include a sub-system 1160 such as a system on a chip (SOC) or an integrated system of multiple ICs, which is illustrated with respect to mobile computing platform 1105.

Whether disposed within integrated system 1110 illustrated in expanded view 1120 or as a stand-alone packaged device within data server machine 1106, sub-system 1160 may include memory circuitry and/or processor circuitry 1140 (e.g., RAM, a microprocessor, a multi-core microprocessor, graphics processor, etc.), a power management integrated circuit (PMIC) 1130, a controller 1135, and a radio frequency integrated circuit (RFIC) 1125 (e.g., including a wideband RF transmitter and/or receiver (TX/RX)). As shown, one or more IC dice, such as memory circuitry and/or processor circuitry 1140 may be assembled and implemented such that one or more are incorporated in a system having a capacitor module (decoupling capacitor boost module) as described herein. In some embodiments, RFIC 1125 includes a digital baseband and an analog front end module further comprising a power amplifier on a transmit path and a low noise amplifier on a receive path). Functionally, PMIC 1130 may perform battery power regulation, DC-to-DC conversion, etc., and so has an input coupled to battery 1115, and an output providing a current supply to other functional modules. As further illustrated in FIG. 11, in the exemplary embodiment, RFIC 1125 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1140 may provide memory functionality for sub-system 1160, high level control, data processing and the like for sub-system 1160. In alternative implementations, each of the SOC modules may be integrated onto separate ICs coupled to a package substrate, interposer, or board.

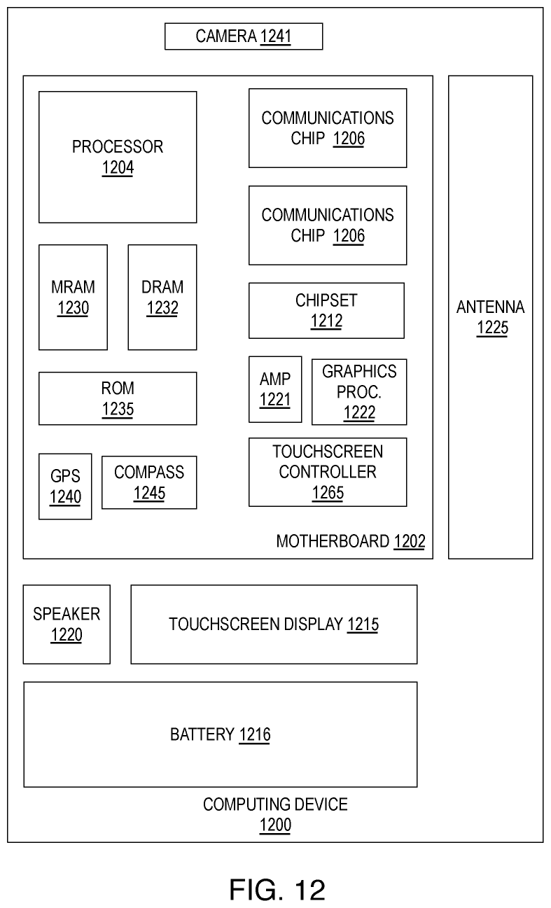

FIG. 12 is a functional block diagram of an electronic computing device 1200, in accordance with some embodiments. For example, device 1200 may, via any suitable component therein, employ a capacitor module (decoupling capacitor boost module) in accordance with any embodiments described elsewhere herein. For example, the capacitor module may be soldered to capacitors attached to motherboard 1202. Device 1200 further includes a motherboard or package substrate 1202 hosting a number of components, such as, but not limited to, a processor 1204 (e.g., an applications processor). Processor 1204 may be physically and/or electrically coupled to package substrate 1202. In general, the term “processor” or “microprocessor” may refer to any device or portion of a device that processes electronic data from registers and/or memory to transform that electronic data into other electronic data that may be further stored in registers and/or memory.

In various examples, one or more communication chips 1206 may also be physically and/or electrically coupled to the motherboard 1202. In further implementations, communication chips 1206 may be part of processor 1204. Depending on its applications, computing device 1200 may include other components that may or may not be physically and electrically coupled to motherboard 1202. These other components include, but are not limited to, volatile memory (e.g., DRAM 1232), non-volatile memory (e.g., ROM 1235), flash memory (e.g., NAND or NOR), magnetic memory (MRAM 1230), a graphics processor 1222, a digital signal processor, a crypto processor, a chipset 1212, an antenna 1225, touchscreen display 1215, touchscreen controller 1265, battery 1216, audio codec, video codec, power amplifier 1221, global positioning system (GPS) device 1240, compass 1245, accelerometer, gyroscope, speaker 1220, camera 1241, and mass storage device (such as hard disk drive, solid-state drive (SSD), compact disk (CD), digital versatile disk (DVD), and so forth, or the like.

Communication chips 1206 may enable wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1206 may implement any of a number of wireless standards or protocols, including, but not limited to, those described elsewhere herein. As discussed, computing device 1200 may include a plurality of communication chips 1206. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus or microelectronic device comprises an integrated circuit (IC) device attached to a surface of a microelectronics board, at least one first capacitor attached to the surface of the microelectronics board and coupled to the IC device, and a capacitor module comprising at least one second capacitor attached to a first surface of a substrate and coupled to the IC device, wherein a second surface of the substrate is attached to the first capacitor, and wherein the first capacitor and the second capacitor are vertically stacked over the microelectronics board.

In one or more second embodiments, further to the first embodiments, a first terminal of the second capacitor is coupled to a first terminal of the first capacitor by a first via extending through the substrate and a second terminal of the second capacitor is coupled to a second terminal of the first capacitor by a second via extending through the substrate.

In one or more third embodiments, further to the first or second embodiments, the first terminals of the first and second capacitors are directly routed to a first interconnect of the IC device by a shared electrical routing.

In one or more fourth embodiments, further to the first through third embodiments, the first capacitor has a perimeter thereof, and wherein at least a portion of the second capacitor is vertically aligned within the perimeter of the first capacitor.

In one or more fifth embodiments, further to the first through fourth embodiments, the first and second capacitors have a shared lateral form factor and are directly vertically aligned such that a centerline of the first capacitor and a centerline of the second capacitor are aligned.

In one or more sixth embodiments, further to the first through fifth embodiments, the apparatus or microelectronic device further comprises a plurality of stacks of capacitors, each of the stacks of capacitors comprising a first level capacitor attached to the surface of the microelectronics board and a second level capacitor over the first level capacitor with the substrate therebetween.

In one or more seventh embodiments, further to the first through sixth embodiments, each of the of capacitors stacks of capacitors comprises a vertically aligned power via and a vertically aligned ground via directly connecting corresponding electrodes of the first and second level capacitors.

In one or more eighth embodiments, further to the first through seventh embodiments, the second surface of the substrate is attached to the first capacitor by a solder joint between a via within the substrate and an electrode of the first capacitor.

In one or more ninth embodiments, further to the first through eighth embodiments, the substrate comprises a cored substrate or a coreless substrate.

In one or more tenth embodiments, further to the first through ninth embodiments, one of the first capacitor or the second capacitor comprises a multi-plate capacitor.

In one or more eleventh embodiments, a system comprises the apparatus or microelectronic device and a power supply coupled to the microelectronics board.

In one or more twelfth embodiments, a system comprises a microelectronics board, an integrated circuit (IC) device attached to a surface of the microelectronics board, a plurality of capacitor stacks each attached to the surface of the microelectronics board, each capacitor stack comprising a first level capacitor attached to the surface of the microelectronics board, a second level capacitor directly attached to the first level capacitor, and a portion of a substrate therebetween, and a power supply coupled to the motherboard.

In one or more thirteenth embodiments, further to the twelfth embodiments, a first terminal of the second level capacitor is coupled to a first terminal of the first level capacitor by a power via extending through the and a second terminal of the second level capacitor is coupled to a second terminal of the first level capacitor by a ground via extending through the substrate.

In one or more fourteenth embodiments, further to the twelfth or thirteenth embodiments, the first level capacitor has a perimeter thereof, and wherein at least a portion of the second level capacitor is vertically aligned within the perimeter of the first capacitor.

In one or more fifteenth embodiments, further to the twelfth through fourteenth embodiments, the substrate is attached to the first capacitor by a solder joint between a via within the substrate and an electrode of the first capacitor.

In one or more sixteenth embodiments, further to the twelfth through fifteenth embodiments, the substrate comprises a cored substrate or a coreless substrate.

In one or more seventeenth embodiments, a method comprises attaching one or more first capacitors to a microelectronics board, attaching one or more second capacitors to a substrate, and attaching the substrate to the one or more first capacitors, wherein said attaching forms one or more capacitor stacks each comprising vertically aligned first and second capacitors with a portion of the substrate therebetween.

In one or more eighteenth embodiments, further to the seventeenth embodiments, a first terminal of the one or more second capacitors is coupled to a first terminal of the one or more first capacitors by a power via extending through the substrate and a second terminal of the one or more second capacitor is coupled to a second terminal of the one or more first capacitor by a ground via extending through the substrate.

In one or more nineteenth embodiments, further to the seventeenth or eighteenth embodiments, the one or more first capacitors each have a perimeter thereof, and wherein at least a portion of the corresponding one or more second capacitors are vertically aligned within the perimeters of the one or more first capacitors.

In one or more twentieth embodiments, further to the seventeenth through nineteenth embodiments, attaching the substrate to the one or more first capacitors comprises a forming a solder bond between the substrate and the one or more first capacitors.

In one or more twenty-first embodiments, further to the seventeenth through twentieth embodiments, the method further comprises attaching an integrated circuit (IC) package to the microelectronics board.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
an integrated circuit (IC) device attached to a surface of a microelectronics board;
at least one first capacitor attached to the surface of the microelectronics board and coupled to the IC device; and
a capacitor module comprising at least one second capacitor attached to a first surface of a substrate and coupled to the IC device, wherein a second surface of the substrate is attached to the first capacitor, and wherein the first capacitor and the second capacitor are vertically stacked over the microelectronics board.

2. The apparatus of claim 1, wherein a first terminal of the second capacitor is coupled to a first terminal of the first capacitor by a first via extending through the substrate and a second terminal of the second capacitor is coupled to a second terminal of the first capacitor by a second via extending through the substrate.

3. The apparatus of claim 2, wherein the first terminals of the first and second capacitors are directly routed to a first interconnect of the IC device by a shared electrical routing.

4. The apparatus of claim 1, wherein the first capacitor has a perimeter thereof, and wherein at least a portion of the second capacitor is vertically aligned within the perimeter of the first capacitor.

5. The apparatus of claim 1, wherein the first and second capacitors have a shared lateral form factor and are directly vertically aligned such that a centerline of the first capacitor and a centerline of the second capacitor are aligned.

6. The apparatus of claim 1, further comprising:
a plurality of stacks of capacitors, each of the stacks of capacitors comprising a first level capacitor attached to the surface of the microelectronics board and a second level capacitor over the first level capacitor with the substrate therebetween.

7. The apparatus of claim 6, wherein each of the of capacitors stacks of capacitors comprises a vertically aligned power via and a vertically aligned ground via directly connecting corresponding electrodes of the first and second level capacitors.

8. The apparatus of claim 1, wherein the second surface of the substrate is attached to the first capacitor by a solder joint between a via within the substrate and an electrode of the first capacitor.

9. The apparatus of claim 1, wherein the substrate comprises a cored substrate or a coreless substrate.

10. The apparatus of claim 1, wherein one of the first capacitor or the second capacitor comprises a multi-plate capacitor.

11. A system, comprising:
a microelectronics board;
an integrated circuit (IC) device attached to a surface of the microelectronics board;
a plurality of capacitor stacks each attached to the surface of the microelectronics board, each capacitor stack comprising a first level capacitor attached to the surface of the microelectronics board, a second level capacitor directly attached to the first level capacitor, and a portion of a substrate therebetween; and
a power supply coupled to the motherboard.

12. The system of claim 11, wherein a first terminal of the second level capacitor is coupled to a first terminal of the first level capacitor by a power via extending through the substrate and a second terminal of the second level capacitor is coupled to a second terminal of the first level capacitor by a ground via extending through the substrate.

13. The system of claim 11, wherein the first level capacitor has a perimeter thereof, and wherein at least a portion of the second level capacitor is vertically aligned within the perimeter of the first capacitor.

14. The system of claim 11, wherein the substrate is attached to the first capacitor by a solder joint between a via within the substrate and an electrode of the first capacitor.

15. The system of claim 11, wherein the substrate comprises a cored substrate or a coreless substrate.

16. A method, comprising:
attaching one or more first capacitors to a microelectronics board;
attaching one or more second capacitors to a substrate; and
attaching the substrate to the one or more first capacitors, wherein said attaching forms one or more capacitor stacks each comprising vertically aligned first and second capacitors with a portion of the substrate therebetween.

17. The method of claim 16, wherein a first terminal of the one or more second capacitors is coupled to a first terminal of the one or more first capacitors by a power via extending through the substrate and a second terminal of the one or more second capacitors is coupled to a second terminal of the one or more first capacitors by a ground via extending through the substrate.

18. The method of claim 16, wherein the one or more first capacitors each have a perimeter thereof, and wherein at least a portion of the corresponding one or more second capacitors are vertically aligned within the perimeters of the one or more first capacitors.

19. The method of claim 16, wherein attaching the substrate to the one or more first capacitors comprises a forming a solder bond between the substrate and the one or more first capacitors.

20. The method of claim 16, further comprising:
attaching an integrated circuit (IC) package to the microelectronics board.
